(19) United States
(12) Patent Application Publication
(10) Pub. No.: US 2002/0021139 A1
(43) Pub. Date: Feb. 21, 2002

(54) Molecular probe station

(75) Inventor: Thomas N. Jackson, State College, PA (US)

Correspondence Address: Paul D. Greeley, Esq., Ohlandt, Greeley, Ruggiero & Perle, L.L.P., 10th Floor, One Landmark Square, Stamford, CT, 06901-2682, US

(73) Assignee: The Penn State Research Foundation

(21) Appl. No.: 09/882,815

(22) Filed: Jun. 15, 2001

Related U.S. Application Data
(60) Provisional application No. 60/212,160, filed on Jun. 16, 2000.

(51) Int. Cl. G01R 31/02

(52) U.S. Cl. 324/762

(57) ABSTRACT

The present invention provides a method and system for measuring an electrical characteristic on a molecular scale including the steps of probing a molecular layer or structure of interest using an atomic force microscopsy (AFM) cantilever having a large contact area probe tip wherein the force applied to the probe tip is controlled and, in response to the probing, at least one electrical characteristic of the molecular layer is detected.

This patent application is based on and claims priority from U.S. Provisional Pat. application No. 60/212,160, filed on Jun. 16, 2000.

### BACKGROUND OF THE INVENTION

1. Field of the Invention

The present invention relates to the field of molecular measurements and, more particularly to a method and system for measuring the electrical characteristics of molecular layers.

2. Description of the Related Art

As research and development yields a greater understanding of molecular and supramolecular structures, including self-assembled monolayers (SAMs), there is a growing interest in using such molecular layers for a variety of electronic and/or materials applications. The physical properties of molecular layers can be characterized using a number of techniques, such as, for example, ellipsometry, infrared spectroscopy, or scanning probe microscopy (SPM). SPM has been used extensively for the imaging and characterization of the physical properties of molecular structures. Much of the focus of SPM is directed at producing images or data with high lateral resolution. Thus, probes having sharp tips have been used in SPM.

Scanning tunneling microscopy (STM) has been proposed for use in determining the electrical characteristics of molecular layers. However, the intrinsic, molecular electrical characteristics of the sampled molecular layers using STM is difficult to deconvolve from the tip tunneling current thereof. In an alternative approach the conductance and capacitance characteristics of self-assembled monolayers on mercury in capillary tubes has been measured. This technique however is limited to applications using liquid metal contacts (e.g., Hg), relatively large size and where the molecular layers that will form on such contacts with low defect density.

Conductive tip atomic force microscopy (AFM) has also been proposed to characterize molecular layers. A disadvantage associated with using conventional AFM to determine the electrical characteristics of molecular levels is that the results vary widely in relation to the applied tip force of the AFM probe. Additionally, the small radius or contact area of the AFM probe tip makes it very difficult, and sometimes impossible, to obtain molecular-level electrical measurements using low applied tip pressure.

The study of self-assembled monolayers (SAMs) is of great interest due to the many potential and expected molecular and electronic applications for SAMs. For example, negative differential resistance and memory effects have been demonstrated in molecular layers. Thus, it is believed that SAMs may be useful as nanoscale memory and other nanotechnology devices.

Considerable work has been done with thiol-based SAMs that have an alkyl or derivatized-alkyl group chain and a surface-active head group which can chemisorb onto the surface of a substrate. Thiol-based SAMs are good candidates for use in nano- and molecular-scale electronic devices because of their ability to bond to metal surfaces such as, for example, Au, Cu, Ag, etc. SAMs are also valued for use in nanotechnology since they form stable, highly organized layers. It has been found that the device characteristics of organic thin film transistors are improved by treating the source and drain contacts thereof with a charge transfer (CT) agent that can selectively, chemically bond to the metal surface and form a stable contact modification. Thiol-based SAMs can thus fulfill this role.

Several methods for characterizing the electrical properties of molecular layers have been proposed. Nanopore membranes fabricated and used to measure the conduction through a small number of organic molecules is one example. The nanopore structure is typically constructed of a SAM sandwiched between a Au-Ti top electrode and a Au bottom electrode. This approach is capable of providing reliable measurements. A disadvantage of using nanpore membranes is the complexity involved in nanopore fabrication. In another method, Hg-SAM/SAM-Hg junctions have been made in a capillary to measure the capacitance of SAMs. Disadvantages of using this and other such techniques include the large active area involved, and the necessity of using a liquid metal (Hg). In yet another proposed approach, metal-SAM-metal tunnel junctions were made using conductive AFM tips, wherein the current-voltage characteristics of alkanethiol monolayers were measured. The observed current results have been found to be heavily correlated and dependent on the applied tip forces, and the interacting area between the AFM probe tip. Accordingly, reliable measurement and characterization of the electrical properties of the SAMs were not achieved or even reliably estimated using conventional AFM.

The experimental AFM measurements were conducted using, for example, a large applied pressure of about 10⁶ Pa (estimated) from a force of 1 nN and a tip radius of 10 nm. The use of such pressure may cause large penetration into the sample SAM, thereby disturbing or otherwise contaminating the SAM and distorting the SAM's associated electrical characteristics.

### SUMMARY OF THE INVENTION

Self-assembled monolayers (SAMs) are of great interest for molecular electronics and other applications. A method to easily characterize the electronic properties of SAMs is important for rapid material evaluation and optimization. In this study, we have probed SAMs using a smooth, large-diameter spherical surface. The sphere is conductive or is coated with a conducting film and distributes force over a large area, resulting in small penetration of SAMs. We have used a simple model for the area-force relationship and have obtained I-V characteristics of alkanethiols using this conducting ball-tip AFM technique.

The molecular probe station of the present invention may be used wherever the electrical properties of a molecular layer, including multiple molecular layers, SAMs, and or supramolecular structures, are of interest. By way of example, such areas of use include, but are not limited to, conductors, semiconductors, batteries, particularly organic- based batteries, and organic semiconductor devices (e.g., organic light emitting diodes, organic thin film transistors, etc.), and molecular electronic devices. Use of the molecular probe station of the present invention may also be extended to determine the electrical characteristics of molecular layers used in applications not normally considered electrical in nature, such as, for example, molecular layers used for corrosion protection, material coupling, and adhesion promotion.

The present invention provides a method and system for detecting and measuring electrical characteristics, such as, but not limited to, voltage, current, capacitance, conductance, resistance, and impedance, on a molecular scale. In particular, the present invention provides a method and system for easily and reliably measuring the electrical characteristics of molecular layers and other molecular scale structures using scanning probe microscopy (SPM) techniques, namely atomic force microscopy (AFM). An important aspect of the present invention is that the AFM cantilever has a relatively large contact area or radius tip, as compared to the surface defects of the molecular surface being measured. The large contact area of the probe tip is in contrast to the small radius probe tips used in conventional AFM. The large contact area of the probe tip distributes the applied force to a greater surface area of the molecular surface being tested. Thus, penetration, and disruption, of the molecular layer being measured is minimized, thereby enabling an accurate measurement of the intrinsic electrical characteristics thereof.

The present invention provides a method for measuring an electrical characteristic on a molecular scale including the steps of probing a molecular layer or structure of interest using an AFM cantilever having a large contact area probe tip wherein the force applied to the probe tip is controlled and, in response to the probing, at least one electrical characteristic of the molecular layer is detected.

In accordance with the present invention, a system is provided for measuring electrical characteristic on a molecular scale using an AFM cantilever having a large contact area probe tip for probing the molecular layer by controlling the applied force of the probe tip, wherein the system includes a meter for detecting the electrical characteristic of the molecular layer, in response to the probing of the molecular layer, coupled to the molecular layer and the AFM cantilever.

The above and other objects, advantages, and benefits of the present invention will be understood by reference to following description and drawings.

### BRIEF DESCRIPTION OF THE DRAWINGS

FIG. 1 is an atomic force microscopy (AFM) setup;

FIG. 2 is a SEM image of a large radius microsphere attached to the cantilever of a AFM in accordance with the teachings herein;

FIG. 3 depicts a simplified test set-up for detecting an electrical characteristic of a molecular layer in accordance with the teachings herein;

FIG. 4 is a graph depicting the relationship between the applied force and contact area for a large radius sphere attached to a AFM cantilever for probing a self assembled monolayer in the present invention;

FIG. 5 is an exemplary graph depicting the relationship between the current and tip bias (Log (I)-V) at various applied forces for a 1-dodecanethiol (C₁₂H₂₅) SAM layer, in accordance with the present invention;

FIG. 6 is an exemplary graph depicting the relationship between the current and tip bias (Log (I)-V) at various applied forces for a 1-octadecanethiol (C₁₈H₃₇) SAM layer, in accordance with the present invention;

FIG. 7 is an exemplary graph depicting the relationship between the current and tip bias (I-V) at various applied forces for a 1-octadecanethiol (C₁₈H₃₇) SAM layer, in accordance with the present invention; and

FIG. 8 shows an exemplary graph of the current voltage relationship of a conductive layer in the absence of an overlying SAM layer, in accordance with the present invention.

### DESCRIPTION OF THE INVENTION

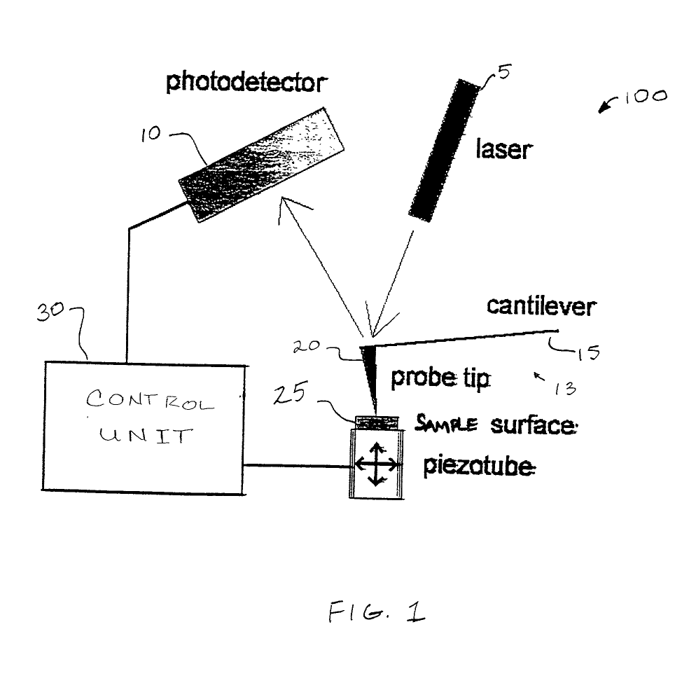

To provide a technical context for the teachings of this invention, a brief description of AFM will be discussed. AFM scans the surface of a subject object or sample using a probe having a cantilever and a very sharp (i.e., very small contact area, 1-50 nm radius of curvature) probe tip. With reference to FIG. 1, there is shown an AFM 100. AFM 100 may be used to generate images by measuring the atomic interactions between the probe tip 20 and the sample surface 25. Measuring the deflection of cantilever 15 produces the topographical image. The deflection of cantilever 15 due to atomic interactions between the probe tip and surface sample 25 is detected by reflecting a laser 5 off of the back of cantilever 15 onto position sensitive photodetector 10 that detects the angle of the of reflection of the laser beam. Photodetector 10 is connected to control unit 30. Feedback from photodetector 10 is used by control unit 30 to maintain probe tip 20 at a constant force on the sample surface 25. Thus, a three-dimensional topographic image is produced by monitoring the motion of the probe tip in the three orthogonal directions (x, y, z) due to motion of probe tip 20 due to the atomic interactions of probe tip 20 and surface sample 25, and the movement of the sample.

The resolution of the images produced by AFM is related to the size of the probe tip. Since higher resolution images and characterization of the physical (i.e., composition) property measurements is a primary objective of AFM, sharper and smaller probe tips have been a design goal and objective. Probe tips down to about 10 nm or less have been obtained. In general, smaller probe tips provide images having greater lateral resolution. For electrical measurements the applied tip force in AFM is an important factor for achieving reliable results. However, an accurate description of the shape of ultrasmall probe tips is difficult to determine and typically not known, thus an accurate determination of the tip pressure cannot be known. This is true even in the case where the total tip force is known. Also, ultrasmall probe tips are not easily produced or readily available.

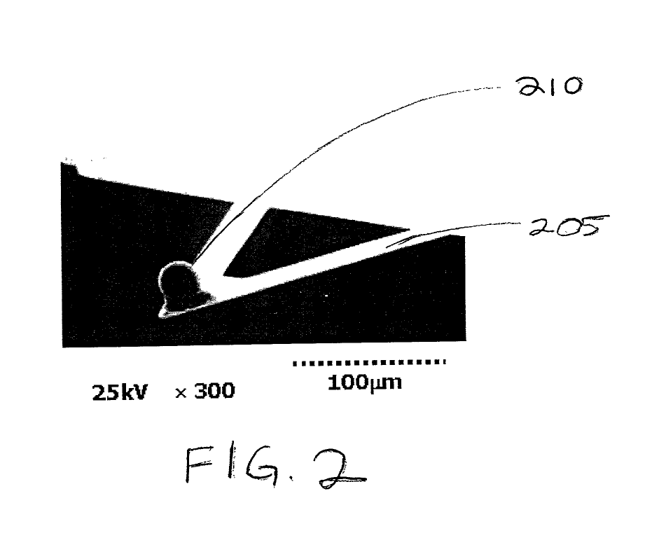

FIG. 2 shows a scanning electronic microscope (SEM) image 200 of a sphere 210, suitable for use in the present invention. Sphere 210, as will be described in greater detail below, forms the probe tip. Sphere 210 is shown attached to cantilever 205. The present invention uses a probe tip having a relatively large radius sphere 210, as compared to the molecular-scale surface defects of a sample being measured. That is, sphere 210 is sized so as not to penetrate the defects of the sample being measured. Sphere 210 may have a radius from about 1 micron and greater. In this manner, the pressure of the large radius probe tip on a molecular surface will not deform the molecular layer of the sample as a result of the probe tip (e.g., sphere 210) penetrating the molecular layer.

Spheres forming a probe tip, in accordance with the present invention, may be as large as 1 mm. Regarding the upper size limits of sphere 210, the mass of sphere 210 is generally related to the acceptable mass cantilever 205 can support without sacrificing performance of the probe tip-cantilever assembly. Thus, a portion of a sphere or portion of other surfaces having a radius or non-constant radius, even greater than 1 mm can be used in accordance with the present invention.

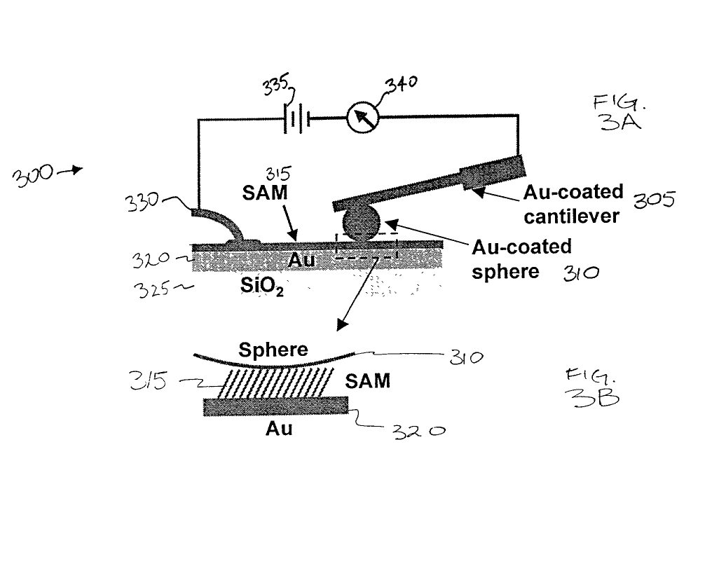

FIG. 3 is a depiction of an exemplary, though simplified, test configuration 300 used to demonstrate the teachings of the present invention. In an aspect of the present invention as mentioned above, the large radius probe tip 310 enables reliable, reproducible quantitative data collection since the large radius probe tip 310 does not deform the molecular layer of the gold (Au) sample 315. That is, reproducible characterization of the gold sample SAM 315 layer is attainable since the molecular layer of the SAM sample is unchanged by the pressure of the large radius tip 310 applied thereto. Furthermore, the large radius probe tip distributes the force applied over a larger contact area.

The present invention can be used in a variety of applications, including applications requiring low contact force between the SPM probe tip and the molecular sample under test. The ability to use low contact force minimizes the contamination and/or disruption (i.e., the destruction) of the intrinsic electrical properties of the molecular structure under test. For devices or samples that require low contact pressure, AFM using the large probe tip taught by the present invention offers advantageous measurement benefits.

Spheres suitable for use include both glass and polymer spheres with radii from a few tens of nanometers to a few tens of microns or even larger, and are readily available. Suitable measurement tips can easily be constructed by using an adhesive to mount a sphere or other curved surface on a conventional AFM cantilever (with or without small radius tip) using, for example, a conductive epoxy. If a non-conductive sphere or cantilever is used, it can easily be made conductive by depositing a thin layer of metal on the probe tip-cantilever assembly. Also, a cantilever having a large radius tip in accordance with the teachings of the present invention can be specifically manufactured, foregoing modification of an existing cantilever.

Cantilevers modified as described herein can be used to characterize both metal surface and molecular layers. For metal surfaces, the present invention measures the expected low resistance contact (i.e., short circuit) pressures for tip forces as low as 0.1 nN. The present invention can use a wide variety of metals, alloys, semiconductors, semimetals, or other conductors to coat the large radius probe tip. With proper system design it can also allow measurements to be made over a wide range of temperature or with other environmental parameters such as gas ambient or optical stimulation. For example, it might be of interest to measure molecular layers over a wide temperature range including low temperature. This could be easily done by measuring in a dry gas environment or in vacuum to avoid moisture condensation on a cooled surface. It may also be of interest to measure changes in the molecular layer electrical characteristics with optical stimulation or before and after exposure to a chemical agent (either in a gas or liquid fluid environment).

The method of the present invention to probe the SAM surface using a smooth, large-radius conductive surface will be described with reference to FIGS. 3A and 3B. Using the large radius probe tip 310 enables the force applied thereto to be distributed over a larger area of SAM 315, thereby causing less penetration of the probe tip 310 into SAM 315.

SAMs are rarely perfect. For example, the molecules are typically arranged at an angle other than 90 degrees (i.e., normal) with respect to the substrate. Thus, tilt boundaries between small molecular domains may result. Other defects include, but are not limited to, for example, molecules inserted upside down, impurity molecules or atoms, dirt or substrate protrusions. Therefore, it is difficult to characterize SAMs electrically by just depositing a metal electrode. The molecular probe station of the present invention is relatively immune to such defects since the large radius of the probe tip will not penetrate into small defects (i.e., defects which are small relative to the probe radius).

Probe tip 310 is prepared using a 25 μm diameter polystyrene sphere is attached to a silicon AFM cantilever using conductive epoxy. The 25 μm diameter polystyrene sphere used is easily manufactured, has well defined physical characteristics, and is readily available. A 50 nm conductive chromium/gold (Cr/Au) layer is deposited onto the probe tip-AFM cantilever assembly using, for example, ion-beam sputtering. The resulting gold coating is a smooth, conductive metal surface. In order to facilitate the application of gold to the probe tip-cantilever assembly, the thin chromium layer, approximately 10 nm, is deposited on the probe tip-cantilever assembly before the gold. The chromium coating aids the adhesion of Au layer to the probe tip-AFM cantilever assembly.

It is noted that other techniques for depositing the chromium/gold layer (or other molecular layers) may be used, such as, but not limited to, sputtering, evaporation, ion beam sputtering, physical vapor deposition, chemical vapor deposition, and electrodeposition. The particular method used may depend on the probe tip used. In the case where a glass or plastic probe tip is used, ion beam deposition or sputtering is particularly useful since a smooth layer of the deposited molecular layer (e.g., Au) is the result.

The electrical characteristics of interest include, but are not limited to, voltage, current, capacitance, conductance, resistance, and impedance. Gold sample 320 is prepared for measuring the electrical characteristics thereof by, for example, ion-beam deposition of chromium/gold on an oxidized silicon (SiO₂) substrate. The undercoating of chromium is first applied for the same reasons stated above. The Gold SAM layer 315 is fabricated by, for example, immersing substrates with gold films into a solution containing the self-assembly molecule of interest (e.g., gold) for several hours. During the treatment, a monolayer chemisorbs to the gold surface.

To facilitate measurement of the electrical characteristics of the gold SAM 315, an electrical connection is made to SAM 315 using a wire bond. For testing purposes, the molecular layer of test surface of interest can be deposited on a conductive electrode. For other molecular layers, the lateral conductivity of such layers is significant, thereby permitting the contact between the probe tip 310 and the molecular layer (e.g., SAM 315) under test to be slightly offset from the electrode 330. The particular test configuration can thus be varied to accommodate the test materials.

The probe tip 310 of the probe tip-AFM cantilever assembly is brought into contact with the top of SAM 315. An illustration of the contact point between the probe tip 310 and the SAM 315 is shown in FIG. 3B.

The applied force is controlled during the measurement process. Although depicted as a voltage source 335 and meter 340 in FIG. 3A, a semiconductor parameter analyzer, such as for example, a HP 4145B manufactured by Hewlett-Packard Company, can be used to measure the electrical characteristics of the SAM 315. Using the test setup such as that shown in FIG. 3A, the current and voltage (I-V) characteristics of SAM 315 is measured and recorded, at various applied forces.

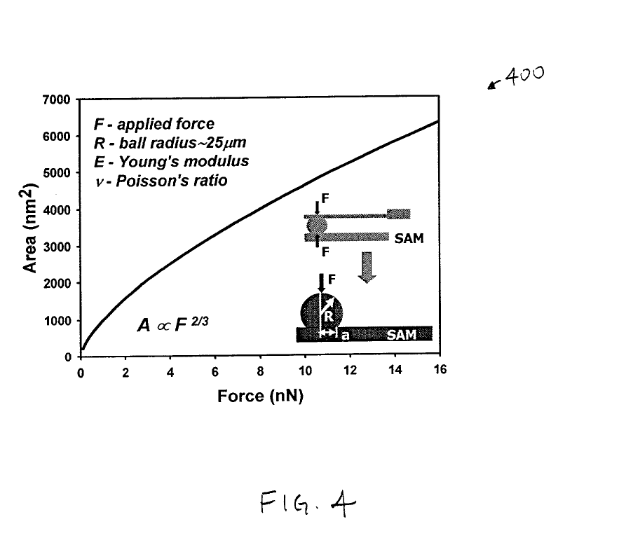

Turning now to the interaction between the probe tip 310 and the SAM 315 under test and FIG. 4, it is assumed that the force is distributed in a circular area having a radius a, and that the elastic properties of the polystyrene sphere used for probe tip 310 and SAM are similar. Thus, the following relationship describing the radius of the interacting area a is applicable:

$$a = {[ \frac{3 π F ( {K}_{1} + {K}_{2} ) R}{4} ]}^{1 / 3} , {K}_{1 , 2} = \frac{1 - {v}_{1 , 2}^{2}}{π {E}_{1 , 2}} \qquad ( 1 )$$

In equation (1), F is the applied force, R is the probe tip sphere radius (˜12.5μm), E is Young's modulus, and v is Poisson's ratio. The subscripts 1 and 2 reference the polystyrene probe tip sphere and the SAM, respectively. It is assumed that E₁=E₂˜2GPa and v₁=v₂˜0.4. FIG. 4 shows an exemplary plot of the interacting area as a function of the applied force using the relationship expressed in equation (1). Although a simplified model, it is seen that a usefully slow change in the area over a wide range of applied force. Accordingly, stable and reliable measurements are obtainable using a large radius probe tip, even over a wide range of applied force.

Note, the equation, and the mechanical constants described above are reasonable assumptions for the sphere and molecular layer used, and may vary depending on the materials used. The voltages used would depend on the desired measurement.

In an aspect of the invention, measurements are taken on bare gold surfaces before and after measuring the SAM layer in order to verify the test set-up, and confirm that the probe tip is not contaminated by the SAM layer. Test measurement is considered valid when a short circuit (i.e., very low resistance) is obtained at a very low applied force (F=0.1 nN), both before and after measuring the electrical characteristics of the SAM.

As an experiment of SAM measurement using the present invention, a gold sample was treated in 1-Dodecanethiol (C₁₂H₂₅) diluted in Ethanol. The thickness of this particular thiol molecule containing a chain of 12 carbon atoms is determined to be 17.4 Å using ellipsometry. If the chain of this molecule is fully extended, and is normal to the surface of the substrate, then the monolayer should be 21 Å. Given these measurements, a tilt angle about 34° is calculated. This is larger than the typical tilt angle of thiols, i.e., about 20° to 25°.

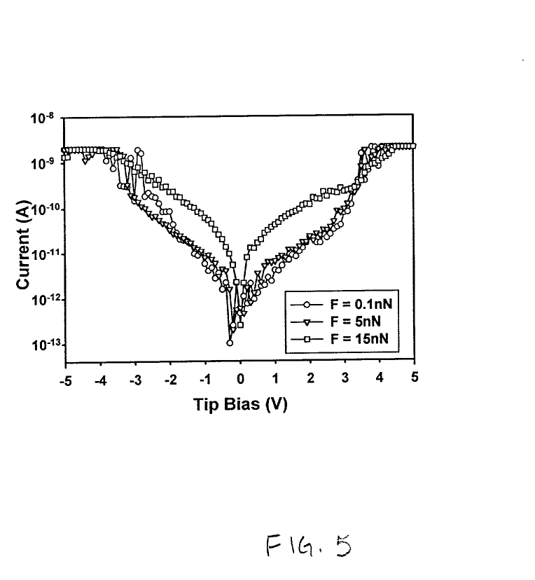

With reference to FIG. 5, the measured Log (I)-V curves for contact forces of 0.1 nN, 5 nN and 15 nN are shown for the above-described SAM. It is noticed that the experimental results exhibit similar quasi-symmetric characteristics, with a substantial region where the measured current varies exponentially with applied bias, for each of the applied contact forces (0.1 nN to 15 nN). Thus, in accordance with the present invention, reliable electrical characteristics of molecular levels can be obtained, even where low applied tip pressure is required (e.g., soft metals and other materials). Since the thiol molecule has different atoms between its head and tail groups respectively, the tunneling effect of electrons may be different for these atoms with the contact metal-gold, giving some degree of asymmetry on the curves.

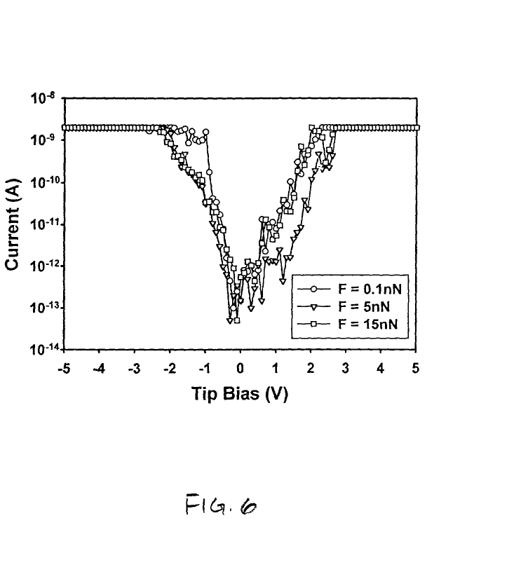

Another test sample, a 1-Octadecanethiol (C₁₈H₃₇) molecule dissolved in dichloromethane, was prepared and measured using the method and system of the present invention. See FIG. 6 for measured results. This thiol has a chain of 18 carbon atoms and a thickness, as measured by ellipsometry, of 21.4 Å. From the estimated thickness for the fully extended chain of 28 Å, the tilt angle is calculated to be 40°. The Log I-V characteristics for this SAM is shown in FIG. 6. It is noted that curves shown in FIG. 5 demonstrates similar characteristics with FIG. 6.

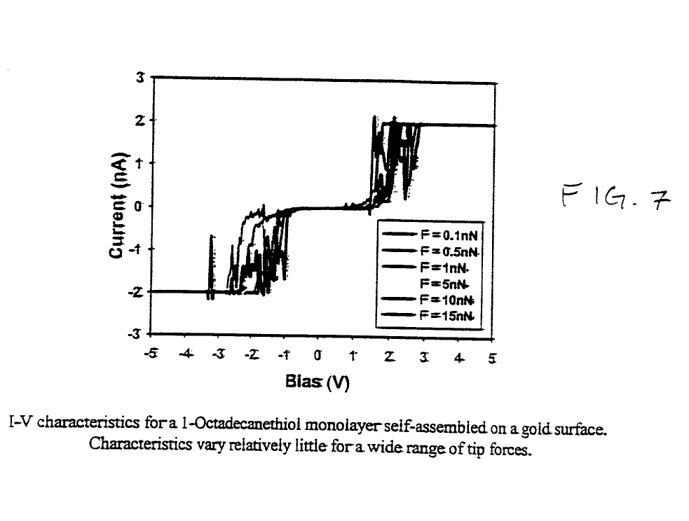

FIG. 7 shows a graph of the I-V relationship curves, at various applied tip forces, for the 1-octadecanethiol SAM on the gold surface. As shown, the measured electrical characteristics vary relatively little over the wide range of applied probe tip forces.

A larger current was measured for 1-octadecanethiol (C₁₈H₃₇) than for the 1-dodecanethiol (C₁₂H₂₅) sample even though the chain length is longer for 1-octadecanethiol. It is believed that this is due to the 1-octadecanethiol layer being less dense than the 1-dodecanethiol layer. This is also indicated by the anomalously large tilt angle calculated using the ellipsometry measurements. Thus, there is an indication that the large radius molecular probe tip technique of the present invention can be used even with SAM layers with surface defects.

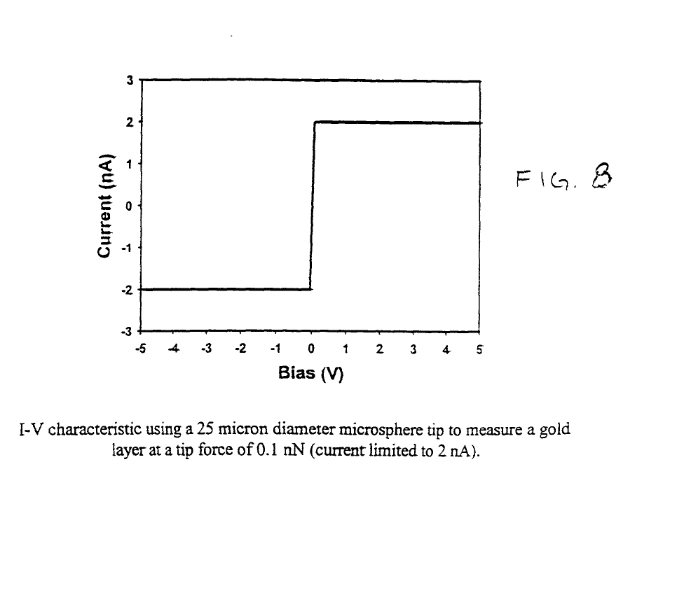

FIG. 8 shows an exemplary current-voltage relationship graph using a using a 25 micron diameter sphere probe tip to measure a gold layer at a tip force of 0.1 nN, wherein the current is limited to 2 nA.

Although described above in the context of specific embodiments, those skilled in the art should appreciate that this description is exemplary and indicative of presently preferred embodiments of the present invention, and is not to be read or construed in a limiting sense upon the invention. For example, the probe tip may have a shape other than a sphere; or to use liquid metals or conductive liquid electrolytes that automatically form a large radius smooth surface (e.g., a drop) as the conductive probe tip; or the molecular layer can include, but not be limited to, a self-assembled monolayer, a thin insulator layer deposited on a substrate, a self-assembled multilayer, a Langmuir-Blodgett film, and a supramolecular structure.

It will be apparent, however, that various variations and modifications may be made to the invention, with the attainment of some or all of the advantages of the invention as indicated in the claims appended hereto.

What I claim is:

9. A method for measuring an electrical characteristic on a molecular scale, said method comprising the steps of:
probing a molecular layer using atomic force microscopy (AFM) having a cantilever including a large contact area probe tip by controlling the force applied to said probe tip; and
detecting, in response to said probing, an electrical characteristic of said molecular layer.

9. The method of claim 1, wherein the large contact area probe tip comprises a large radius sphere affixed to the cantilever.

10. The method of claim 1, wherein the step of probing includes varying the force applied to said probe tip.

11. The method of claim 1, wherein said electrical characteristic is at least one selected from the group consisting of: current, voltage, capacitance, conductance, resistance, and impedance.

12. The method of claim 1, wherein the step of detecting includes coupling said molecular layer, said cantilever, and a meter to each other in a circuit.

13. The method of claim 1, wherein the molecular layer is at least one selected from the group consisting of: a self-assembled monolayer, a thin insulator layer deposited on a substrate, a self-assembled multilayer, a Langmuir-Blodgett film, and a supramolecular structure.

14. The method of claim 1, wherein said molecular layer is assembled by at least one technique selected from the group consisting of: ion beam sputtering, ion beam deposition, evaporation, sputtering, physical vapor deposition, chemical vapor deposition, and electrodeposition.

15. A system for measuring an electrical characteristic on a molecular scale, said system comprising:
a molecular layer, subject to having said electrical characteristic thereof measured;
an atomic force microscope (AFM) including a cantilever having a large contact area probe tip for probing said molecular layer; and
a meter coupled to said molecular layer and said cantilever for detecting said electrical characteristic of said molecular layer in response to said probing of said molecular layer.

9. The system of claim 8, wherein said large contact area probe tip comprises a large radius sphere attached to the cantilever.

10. The system of claim 8, wherein said cantilever and said large contact area probe tip comprise at least an electrically conductive coating, the cantilever and large contact area probe tip are electrically conductive.

11. The system of claim 8, wherein said molecular layer is probed by controlling the force applied to the probe tip.

12. The system of claim 11, wherein said force applied to said probe tip is varied.

13. The system of claim 8, wherein the detected electrical characteristic is at least one selected from the group consisting of: voltage, current, capacitance, conductance, resistance, and impedance.

14. The system of claim 8, wherein the molecular layer is at least one selected from the group consisting of: self assembled monolayer, a supramolecular structure, a self-assembled multilayer, a Langmuir-Blodgett film, and a thin insulator deposited on a substrate.

15. The system of claim 8, wherein the molecular layer is assembled by at least one technique selected from the group consisting of: fluid self-assembly, vapor phase self-assembly, vapor deposition, Langmuir-Blodgett deposition, and reactive self-assembly.
